(19) United States
(12) Patent Application Publication
(10) Pub. No.: US 2026/0150469 A1
(43) Pub. Date: May 28, 2026

(54) DISPLAY DEVICE

(71) Applicant: AUO Corporation, Hsinchu City (TW)

(72) Inventor: Min-Ching Tsai, Hsinchu City (TW)

(73) Assignee: AUO Corporation, Hsinchu City (TW)

(21) Appl. No.: 19/253,960

(22) Filed: Jun. 29, 2025

(30) Foreign Application Priority Data
Nov. 26, 2024 (TW) 113145611

(51) Int. Cl. H10H 29/85; H01L 25/075; H10H 29/37; H10H 29/856

(52) U.S. Cl. CPC H10H 29/8517; H10H 29/37; H10H 29/856; H10W 90/00

(57) ABSTRACT

A display device includes a driving backplane, a bank layer, a first light-emitting element, a first lower optical structure, and a first color conversion structure. The first lower optical structure is disposed in a first opening of the bank layer and covers the first light-emitting element. The first color conversion structure is disposed in the first opening of the bank layer and on a first lower optical structure. The first lower optical structure is located between the first color conversion structure and the first light-emitting element. The first light-emitting element is configured to emit first color light. The first color conversion structure is configured to convert the first color light into second color light. The first lower optical structure is configured to allow the first color light to pass through and reflect the second color light.

### CROSS-REFERENCE TO RELATED APPLICATION

This application claims the priority benefit of Taiwan application serial no. 113145611, filed on Nov. 26, 2024. The entirety of the above-mentioned patent application is hereby incorporated by reference herein and made a part of this specification.

### BACKGROUND

### Technical Field

The disclosure relates to a display device.

### Description of Related Art

A light-emitting diode (LED) display panel includes a driving backplane and a plurality of LED elements transferred onto the driving backplane. Inheriting the characteristics of LEDs, an LED display panel offers advantages such as low power consumption, high efficiency, high brightness, and fast response time. In addition, compared to organic light-emitting diode (OLED) display panels, the LED display panels also provide benefits such as easy color tuning, long emission lifetime, and immunity to image burn-in. Therefore, the LED display panels are considered as the next-generation display technology.

In the current architecture of the LED display panels, the LED elements may be combined with color conversion structures to emit display light beams of desired colors. However, when an excitation light beam emitted by an LED element passes through the color conversion structure to be converted into a display light beam of the desired color, a portion of the display light beam tends to be trapped within the LED display panel and cannot be emitted, resulting in reduced optical efficiency of the LED display panel.

### SUMMARY

The disclosure provides a display device with good optical efficiency.

In one or more embodiments of the disclosure, a display device is provided, and the display device includes a driving backplane, a bank layer, a first light-emitting element, a second light-emitting element, a third light-emitting element, an opposite substrate, a first lower optical structure, and a first color conversion structure. The bank layer is disposed on the driving backplane and has a first opening, a second opening, and a third opening. The first light-emitting element, the second light-emitting element, and the third light-emitting element are located in the first opening, the second opening, and the third opening, respectively, and are electrically connected to the driving backplane. The opposite substrate is disposed opposite to the driving backplane. The first lower optical structure is disposed in the first opening of the bank layer and covers the first light-emitting element. The first color conversion structure is disposed in the first opening of the bank layer and on the first lower optical structure. The first lower optical structure is located between the first color conversion structure and the first light-emitting element. The first light-emitting element is configured to emit first color light. The first color conversion structure is configured to convert the first color light into second color light. The first lower optical structure is configured to allow the first color light to penetrate and reflect the second color light.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a display device according to an embodiment of the disclosure.

FIG. 2 schematically illustrates a first light-emitting element, a first lower optical structure, a first color conversion structure, a first upper optical structure, first color light emitted by the first light-emitting element, and second color light converted by the first color conversion structure of a display device according to an embodiment of the disclosure.

FIG. 3 is a schematic cross-sectional view of a display device according to another embodiment of the disclosure.

FIG. 4 is a schematic cross-sectional view of a display device according to yet another embodiment of the disclosure.

FIG. 5 is a schematic cross-sectional view of a display device according to still another embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like parts.

It should be understood that when a device, such as a layer, a film, a region, or a substrate is referred to as being “on” or “connected to” another element, it can be directly on or connected to the another element, or an intermediate element may also be present. By contrast, when an element is referred to as being “directly on” or “directly connected to” another element, no intermediate element is present. As used herein, being “connected” may refer to a physical and/or electrical connection. Furthermore, being “electrically connected” or “coupled” may refer to the presence of other elements between the two elements.

Considering the particular amount of measurement and measurement-related errors discussed (i.e., the limitations of the measurement system), the terminology “about,” “approximately,” or “substantially” used herein includes the average of the stated value and an acceptable range of deviations from the particular value as determined by those skilled in the art. For instance, the terminology “about” may refer to as being within one or more standard deviations of the stated value, or within ±30%, ±20%, ±10%, or ±5%. Furthermore, the terminology “about,” “approximately,” or “substantially” as used herein may be chosen from a range of acceptable deviations or standard deviations depending on the optical properties, etching properties, or other properties, rather than one standard deviation for all properties.

Unless otherwise defined, all terminologies (including technical and scientific terminologies) used herein have the same meaning as commonly understood by people having ordinary skill in the art to which the disclosure belongs. It is understood that the terminologies, such as those defined in commonly used dictionaries, should be interpreted as having meanings consistent with the relevant art and the background or context of the disclosure, and should not be interpreted in an idealized or overly formal way, unless otherwise defined in the disclosure.

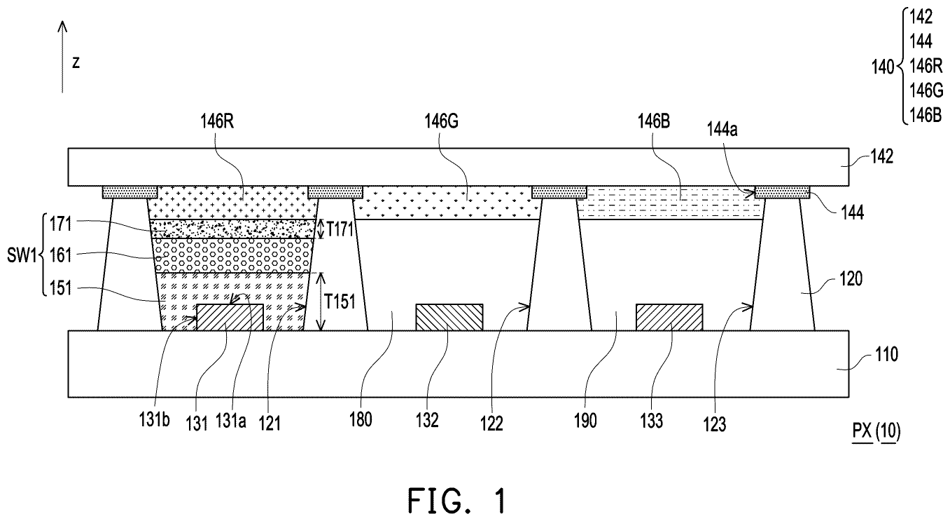

FIG. 1 is a schematic cross-sectional view of a display device according to an embodiment of the disclosure. In FIG. 1, one pixel PX of the display device 10 is illustratively shown. A person skilled in the art may implement the entire display device 10 based on FIG. 1 and the following description; therefore, multiple pixels PX are not repeatedly illustrated herein.

With reference to FIG. 1, the display device 10 includes a driving backplane 110. The driving backplane 110 can include a plurality of sub-pixel driving circuits (not shown). For instance, in an embodiment, each sub-pixel driving circuit can include a first transistor (not shown), a second transistor (not shown), and a capacitor (not shown), wherein a first terminal of the first transistor is electrically connected to a corresponding data line (not shown), a control terminal of the first transistor is electrically connected to a corresponding scan line (not shown), a second terminal of the first transistor is electrically connected to a control terminal of the second transistor, a first terminal of the second transistor is electrically connected to a corresponding power line (not shown), and the capacitor is electrically connected to the second terminal of the first transistor and the first terminal of the second transistor, which should however not be construed as limitations in the disclosure. In other embodiments, the sub-pixel driving circuit can also be in other forms.

The display device 10 further includes a bank layer 120 that is disposed on the driving backplane 110. The bank layer 120 has a first opening 121, a second opening 122, and a third opening 123. In some embodiments, a material of the bank layer 120 can selectively have reflectivity, which should however not be construed as a limitation in the disclosure.

The display device 10 further includes a first light-emitting element 131, a second light-emitting element 132, and a third light-emitting element 133. The first light-emitting element 131, the second light-emitting element 132, and the third light-emitting element 133 are respectively located in the first opening 121, the second opening 122, and the third opening 123 of the bank layer 120. The first light-emitting element 131, the second light-emitting element 132, and the third light-emitting element 133 are respectively electrically connected to the sub-pixel driving circuits of the driving backplane 110.

The first light-emitting element 131, the second light-emitting element 132, and the third light-emitting element 133 are respectively configured to emit first color light, third color light, and fifth color light. For instance, in some embodiments, the first color light, the third color light, and the fifth color light are, for instance, blue light, green light, and blue light, respectively, which should however not be construed as limitations in the disclosure. In some embodiments, the first light-emitting element 131, the second light-emitting element 132, and the third light-emitting element 133 are, for instance, a plurality of light-emitting diode elements (LEDs), which should however not be construed as a limitation in the disclosure. In other embodiments, the first light-emitting element 131, the second light-emitting element 132, and the third light-emitting element 133 can also be other types of light-emitting elements, including but not limited to organic electroluminescent elements and so on.

The display device 10 further includes an opposite substrate 140 that is disposed on the opposite of the driving backplane 110. In some embodiments, the opposite substrate 140 can include a base 142, a light-shielding pattern layer 144 disposed on the base 142, and a plurality of color filter patterns 146R, 146G, and 146B respectively disposed in a plurality of openings 144a of the light-shielding pattern layer 144. In some embodiments, the base 142 can be a transparent base, and a material of the transparent base includes, for instance, glass, quartz, organic polymer, or other applicable materials. In some embodiments, the light-shielding pattern layer 144 can be a black matrix, and a material of the black matrix includes, for instance, black resin or other applicable materials. The color filter patterns 146R, 146G, and 146B have different colors. For instance, in some embodiments, each pixel PX of the display device 10 can include the color filter patterns 146R, 146G, and 146B of the red color, the green color, and the blue color, respectively, which should however not be construed as a limitation in the disclosure.

Each pixel PX of the display device 10 further includes a first lower optical structure 151 that is disposed in the first opening 121 of the bank layer 120 and covers the first light-emitting element 131. Specifically, in some embodiments, the first lower optical structure 151 can cover a top surface 131a and a sidewall 131b of the first light-emitting element 131.

Each pixel PX of the display device 10 further includes a first color conversion structure 161 that is disposed in the first opening 121 of the bank layer 120 and on the first lower optical structure 151. The first lower optical structure 151 is located between the first color conversion structure 161 and the first light-emitting element 131. The first color conversion structure 161 is located between the opposite substrate 140 and the first lower optical structure 151. The first color conversion structure 161 is configured to convert the first color light emitted by the first light-emitting element 131 into second color light. For instance, in some embodiments, the first color conversion structure 161 is configured to convert the blue light emitted by the first light-emitting element 131 into red light, which should however not be construed as a limitation in the disclosure.

In some embodiments, each pixel PX of the display device 10 further includes a first upper optical structure 171 that is disposed in the first opening 121 of the bank layer 120 and on the first color conversion structure 161. The first color conversion structure 161 is located between the first upper optical structure 171 and the first lower optical structure 151. The first upper optical structure 171 is located between the opposite substrate 140 and the first color conversion structure 161. In some embodiments, the thickness T151 of the first lower optical structure 151 in a z direction perpendicular to the driving backplane 110 can be greater than the thickness T171 of the first upper optical structure 171 in the z direction, which should however not be construed as a limitation in the disclosure.

In some embodiments, each pixel PX of the display device 10 can further include a transparent material 180 that is disposed in the second opening 122 of the bank layer 120 and covers the second light-emitting element 132. The transparent material 180 is located between the opposite substrate 140 and the second light-emitting element 132. In some embodiments, the second light-emitting element 132 is configured to emit third color light (not shown), and the third color light can pass through the transparent material 180 and substantially maintain its color. For instance, in some embodiments, the transparent material 180 can include a transparent photoresist or a transparent planarization layer, which should however not be construed as a limitation in the disclosure. In some embodiments, a plurality of scattering particles can be selectively doped in the transparent material 180, which should however not be construed as a limitation in the disclosure.

In some embodiments, each pixel PX of the display device 10 can further include a transparent material 190 that is disposed in the third opening 123 of the bank layer 120 and covers the third light-emitting element 133. The transparent material 190 is located between the opposite substrate 140 and the third light-emitting element 133. In some embodiments, the third light-emitting element 133 is configured to emit fifth color light (not shown), and the fifth color light can pass through the transparent material 190 and substantially maintain its color. For instance, in some embodiments, the transparent material 190 can include a transparent photoresist or a transparent planarization layer, which should however not be construed as a limitation in the disclosure. In some embodiments, a plurality of scattering particles can be selectively doped in the transparent material 190, which should however not be construed as a limitation in the disclosure.

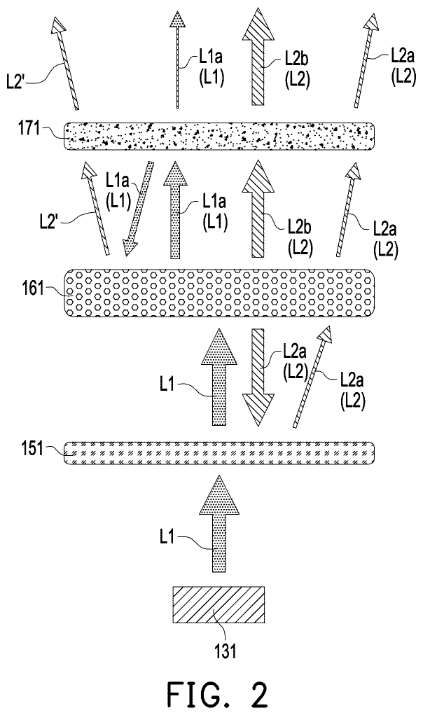

FIG. 2 schematically illustrates a first light-emitting element, a first lower optical structure, a first color conversion structure, a first upper optical structure, first color light emitted by the first light-emitting element, and second color light converted by the first color conversion structure of a display device according to an embodiment of the disclosure.

With reference to FIG. 1 and FIG. 2, it is worth noting that the first light-emitting element 131 is configured to emit first color light L1, the first color conversion structure 161 is configured to convert the first color light L1 into second color light L2, the first lower optical structure 151 is configured to allow the first color light L1 to penetrate and reflect the second color light L2, and the first upper optical structure 171 is configured to allow the second color light L2 to penetrate and reflect the first color light L1.

In detail, the first color light L1 emitted by the first light-emitting element 131 can pass through the first lower optical structure 151 and can be transmitted to the first color conversion structure 161. A portion of the first color light L1 (not shown) can be converted into the second color light L2 by the first color conversion structure 161. The second color light L2 includes a first portion L2a and a second portion L2b, wherein the first portion L2a is substantially transmitted toward the driving backplane 110, and the second portion L2b is substantially transmitted toward the opposite substrate 140. The second portion L2b of the second color light L2 can pass through the first upper optical structure 171 and thereby emit outward. The first portion L2a of the second color light L2 can be reflected by the first lower optical structure 151 back into the first color conversion structure 161 and thereby pass through the first upper optical structure 171 and emit outward. That is, through the reflection provided by the first lower optical structure 151, the emission probability of the second portion L2b of the second color light L2, originally prone to be trapped within the display device 10, can be greatly increased. As a result, the optical efficiency of the display device 10 can be greatly enhanced.

On the other hand, another portion L1a of the first color light L1 transmitted to the first color conversion structure 161 may not be converted into the second color light L2 and continue to move toward the opposite substrate 140. In some embodiments, the portion L1a of the first color light L1 may be reflected by the first upper optical structure 171 back into the first color conversion structure 161 and further reused by the first color conversion structure 161 and converted into second color light L2′. The second color light L2′ can pass through the first upper optical structure 171 and thereby emit outward. That is, the first upper optical structure 171 facilitates the recycling of the portion L1a of the first color light L1 that is not fully utilized by the first color conversion structure 161, increasing the probability of the portion L1a of the first color light L1 being converted into the second color light L2′. As a result, the optical efficiency of the display device 10 is enhanced. At the same time, the leakage of the first color light L1 emitted by the first light-emitting element 131 from the display device 10 can be reduced, thereby improving the color purity of the display device 10.

In brief, in some embodiments, the first color conversion structure 161 is sandwiched between the first upper optical structure 171 and the first lower optical structure 151. By utilizing a sandwich structure SW1 formed by the first color conversion structure 161, the first upper optical structure 171, and the first lower optical structure 151 and based on the optical properties of the first upper optical structure 171 and the first lower optical structure 151, an optical resonant cavity effect can be achieved, allowing internal light to be continuously recycled and reused. Thereby, the optical efficiency of the display device 10 can be greatly enhanced.

In some embodiments, the first lower optical structure 151 can be configured to allow blue light to penetrate and reflect red light, and the first upper optical structure 171 can be configured to allow the red light to penetrate and reflect the blue light. In some embodiments, preferably, the transmittance of the first lower optical structure 151 for the blue light can be greater than 90%, the reflectance of the first lower optical structure 151 for the red light can be greater than 80%, the transmittance of the first upper optical structure 171 for the red light cab be greater than 90%, and the reflectance of the first upper optical structure 171 for the blue light can be greater than 80%, which should however not be construed as limitations in the disclosure.

It must be explained that the following embodiments continue to use the reference numbers and partial content of the aforementioned embodiments, where the same numbers serve to represent the same or similar elements, and explanations of identical technical content are omitted. For explanations of the omitted portions, please refer to the aforementioned embodiments, which will not be repeated in the following embodiments.

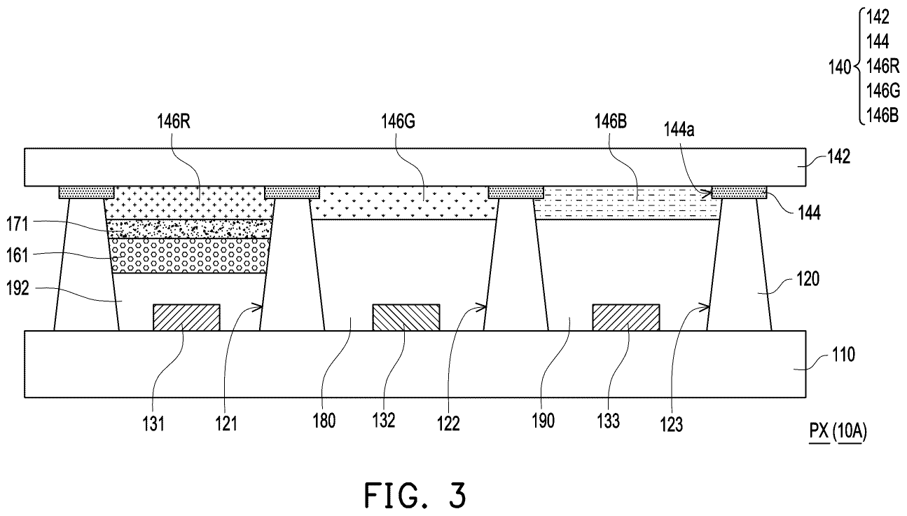

FIG. 3 is a schematic cross-sectional view of a display device according to another embodiment of the disclosure. A display device 10A in FIG. 3 is similar to the display device 10 in FIG. 1, while the difference therebetween lies in that: the display device 10A in FIG. 3 does not include the first lower optical structure 151 depicted in FIG. 1 but includes a transparent material 192. With reference to FIG. 3, the transparent material 192 is disposed in the first opening 121 of the bank layer 120 and covers the first light-emitting element 131, and the transparent material 192 is located between the first color conversion structure 161 and the driving backplane 110. For instance, in some embodiments, the transparent material 192 can include transparent photoresist or a transparent planarization layer, which should however not be construed as a limitation in the disclosure. Although the display device 10A in FIG. 3 does not include the first lower optical structure 151 depicted in FIG. 1, the optical efficiency of the display device 10A can still be enhanced through the first upper optical structure 171.

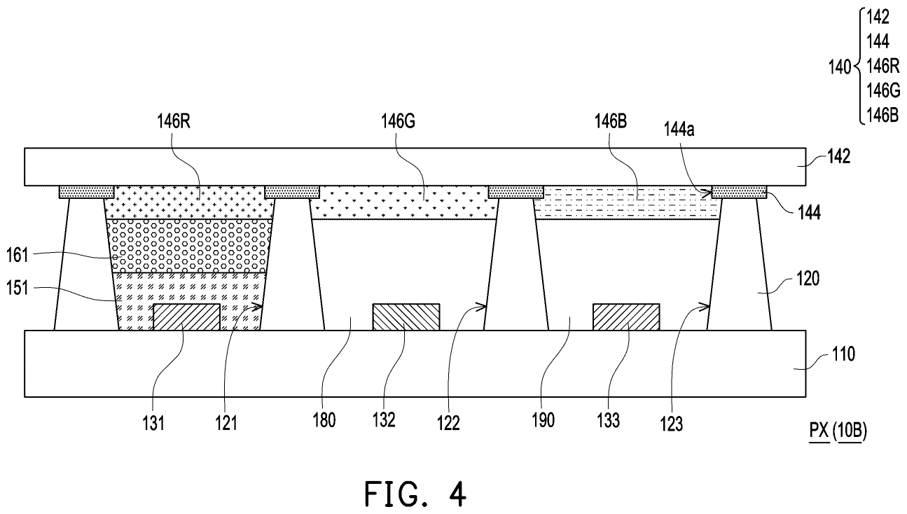

FIG. 4 is a schematic cross-sectional view of a display device according to yet another embodiment of the disclosure. A display device 10B in FIG. 4 is similar to the display device 10 in FIG. 1, while the difference therebetween lies in that: the display device 10B in FIG. 4 does not include the first upper optical structure 171 depicted in FIG. 1. Although the display device 10B in FIG. 4 does not include the first upper optical structure 171 depicted in FIG. 1, the optical efficiency of the display device 10B can still be enhanced through the first lower optical structure 151.

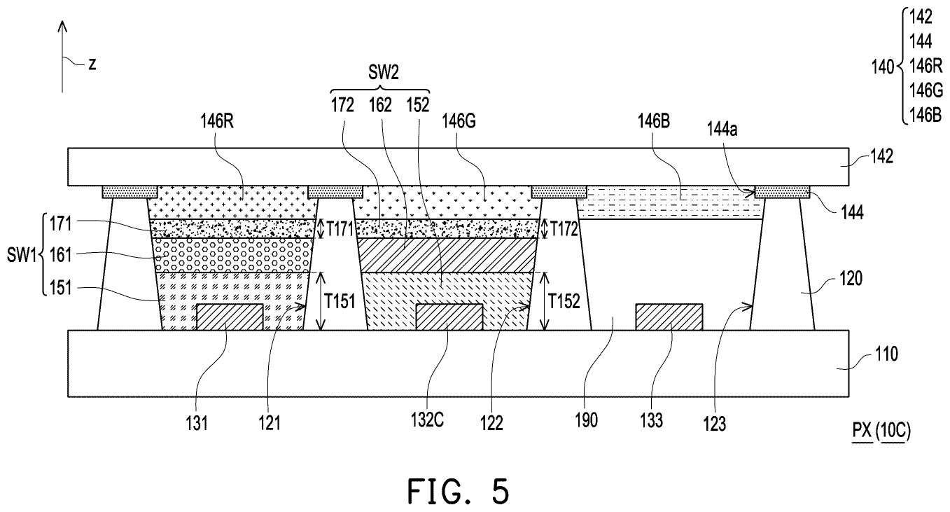

FIG. 5 is a schematic cross-sectional view of a display device according to still another embodiment of the disclosure. A display device 10C in FIG. 5 is similar to the display device 10 in FIG. 1, while the difference therebetween lies in that: the display device 10C in FIG. 5 does not include the transparent material 180 depicted in FIG. 1 but includes a second lower optical structure 152, a second color conversion structure 162, and a second upper optical structure 172.

With reference to FIG. 5, the second lower optical structure 152 is disposed in the second opening 122 of the bank layer 120 and covers the second light-emitting element 132C. The second color conversion structure 162 is disposed in the second opening 122 of the bank layer 120 and on the second lower optical structure 152. The second lower optical structure 152 is located between the second color conversion structure 162 and the second light-emitting element 132C. The second light-emitting element 132C is configured to emit third color light (e.g., the blue light). The second color conversion structure 162 is configured to convert the third color light (e.g., the blue light) to fourth color light (e.g., the green light). The second lower optical structure 152 is configured to allow the third color light (e.g., the blue light) to penetrate and reflect the fourth color light (e.g., the green light).

The second upper optical structure 172 is disposed in the second opening 122 of the bank layer 120 and on the second color conversion structure 162. The second color conversion structure 162 is located between the second upper optical structure 172 and the second lower optical structure 152. The second upper optical structure 172 is located between the opposite substrate 140 and the second color conversion structure 162. The second upper optical structure 172 is configured to allow the fourth color light (e.g., the green light) to penetrate and reflect the third color light (e.g., the blue light).

Similarly, utilizing a sandwich structure SW2 formed by the second color conversion structure 162, the second upper optical structure 172, and the second lower optical structure 152, based on the optical properties of the second upper optical structure 172 and the second lower optical structure 152, can achieve an optical resonant cavity effect, allowing internal light to be continuously recycled and reused. Thereby, the optical efficiency of the display device 10C can be greatly enhanced.

In some embodiments, the second lower optical structure 152 is configured to allow the blue light to penetrate and reflect the green light, and the second upper optical structure 172 is configured to allow the green light to penetrate and reflect the blue light. In some embodiments, preferably, the transmittance of the second lower optical structure 152 for the blue light is greater than 90%, and the reflectance of the second lower optical structure 152 for the green light is greater than 80%, which should however not be construed as limitations in the disclosure. In some embodiments, preferably, the transmittance of the second upper optical structure 172 for the green light is greater than 90%, and the reflectance of the second upper optical structure 172 for the blue light is greater than 80%, which should however not be construed as limitations in the disclosure. In some embodiments, the thickness T152 of the second lower optical structure 152 in the z direction perpendicular to the driving backplane 110 can be greater than the thickness T172 of the second upper optical structure 172 in the z direction, which should however not be construed as a limitation in the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising:
a driving backplane;
a bank layer, disposed on the driving backplane and having a first opening, a second opening, and a third opening;
a first light-emitting element, a second light-emitting element, and a third light-emitting element, located in the first opening, the second opening, and the third opening and electrically connected to the driving backplane;
an opposite substrate, disposed opposite to the driving backplane;
a first lower optical structure, disposed in the first opening of the bank layer and covering the first light-emitting element; and
a first color conversion structure, disposed in the first opening of the bank layer and on the first lower optical structure, wherein the first lower optical structure is located between the first color conversion structure and the first light-emitting element, the first light-emitting element is configured to emit first color light, the first color conversion structure is configured to convert the first color light to second color light, and the first lower optical structure is configured to allow the first color light to penetrate and reflect the second color light.

2. The display device according to claim 1, further comprising:
a first upper optical structure, disposed in the first opening of the bank layer and on the first color conversion structure, wherein the first color conversion structure is located between the first upper optical structure and the first lower optical structure, the first upper optical structure is located between the opposite substrate and the first color conversion structure, and the first upper optical structure is configured to allow the second color light to penetrate and reflect the first color light.

3. The display device according to claim 2, wherein the first lower optical structure is configured to allow blue light to penetrate and reflect red light, and the first upper optical structure is configured to allow the red light to penetrate and reflect the blue light.

4. The display device according to claim 3, wherein a transmittance of the first lower optical structure for the blue light is greater than 90%, and a reflectance of the first lower optical structure for the red light is greater than 80%.

5. The display device according to claim 3, wherein a transmittance of the first upper optical structure for the red light is greater than 90%, and a reflectance of the first upper optical structure for the blue light is greater than 80%.

6. The display device according to claim 1, further comprising:
a second lower optical structure, disposed in the second opening of the bank layer and covering the second light-emitting element; and
a second color conversion structure, disposed in the second opening of the bank layer and on the second lower optical structure, wherein the second lower optical structure is located between the second color conversion structure and the second light-emitting element, the second light-emitting element is configured to emit third color light, the second color conversion structure is configured to convert the third color light to fourth color light, and the second lower optical structure is configured to allow the third color light to penetrate and reflect the fourth color light.

7. The display device according to claim 6, further comprising:
a second upper optical structure, disposed in the second opening of the bank layer and on the second color conversion structure, wherein the second color conversion structure is located between the second upper optical structure and the second lower optical structure, the second upper optical structure is located between the opposite substrate and the second color conversion structure, and the second upper optical structure is configured to allow the fourth color light to penetrate and reflect the third color light.

8. The display device according to claim 7, wherein the second lower optical structure is configured to allow blue light to penetrate and reflect green light, and the second upper optical structure is configured to allow the green light to penetrate and reflect the blue light.

9. The display device according to claim 8, wherein a transmittance of the second lower optical structure for the blue light is greater than 90%, and a reflectance of the second lower optical structure for the green light is greater than 80%.

10. The display device according to claim 8, wherein a transmittance of the second upper optical structure for the green light is greater than 90%, and a reflectance of the second upper optical structure for the blue light is greater than 80%.

11. A display device, comprising:
a driving backplane;
a bank layer, disposed on the driving backplane and having a first opening, a second opening, and a third opening;
a first light-emitting element, a second light-emitting element, and a third light-emitting element, located in the first opening, the second opening, and the third opening and electrically connected to the driving backplane;
an opposite substrate, disposed opposite to the driving backplane;
a first lower optical structure, disposed in the first opening of the bank layer, and covering the first light-emitting element;
a first color conversion structure, disposed in the first opening of the bank layer and on the first lower optical structure, wherein the first lower optical structure is located between the first color conversion structure and the first light-emitting element, the first light-emitting element is configured to emit first color light, and the first color conversion structure is configured to convert the first color light to second color light; and
a first upper optical structure, disposed in the first opening of the bank layer and on the first color conversion structure, wherein the first color conversion structure is located between the first upper optical structure and the first lower optical structure, the first upper optical structure is located between the opposite substrate and the first color conversion structure, and the first upper optical structure is configured to allow the second color light to penetrate and reflect the first color light.

12. The display device according to claim 11, wherein the first lower optical structure is configured to allow blue light to penetrate and reflect red light, and the first upper optical structure is configured to allow the red light to penetrate and reflect the blue light.

13. The display device according to claim 12, wherein a transmittance of the first lower optical structure for the blue light is greater than 90%, a reflectance of the first lower optical structure for the red light is greater than 80%.

14. The display device according to claim 12, wherein a transmittance of the first upper optical structure for the red light is greater than 90%, a reflectance of the first upper optical structure for the blue light is greater than 80%.

15. The display device according to claim 11, further comprising:
a second lower optical structure, disposed in the second opening of the bank layer and covering the second light-emitting element; and
a second color conversion structure, disposed in the second opening of the bank layer and on the second lower optical structure, wherein the second lower optical structure is located between the second color conversion structure and the second light-emitting element, the second light-emitting element is configured to emit third color light, the second color conversion structure is configured to convert the third color light to fourth color light, and the second lower optical structure is configured to allow the third color light to penetrate and reflect the fourth color light.
